(19) United States
(12) Patent Application Publication
(10) Pub. No.: US 2007/0235832 A1
(43) Pub. Date: Oct. 11, 2007

(54) GROUND LAYER OF PRINTED CIRCUIT BOARD

(75) Inventors: Ying-Xin Wang, Shenzhen (CN); Yu-Hsu Lin, San Jose, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,771

(22) Filed: Sep. 22, 2006

(30) Foreign Application Priority Data
Mar. 29, 2006 (CN) 200610060109.X

(51) Int. Cl. H01L 29/00

(52) U.S. Cl. 257/503

(57) ABSTRACT

A ground layer of a printed circuit board (PCB) includes a digital area, an analog area, and a connecting portion. The digital area is connected to the analog area via the connecting portion. The connecting portion with one end connected to the digital area, and the other end connected to the analog area follows a path resembling a labyrinth. The connecting portion replaces a conventional linear connecting portion and a plurality of chip capacitors. The connecting portion improves noise filtering effect and reduces cost as well.

### FIELD OF THE INVENTION

The present invention relates to printed circuit boards (PCBs), and more particularly to a PCB having a ground layer for improving noise filtering effect thereof.

### DESCRIPTION OF RELATED ART

A typical ground layer of a PCB generally includes a digital area, and an analog area. The digital area is a common ground reference area for digital circuits of the PCB. The analog area is a common ground reference area for analog circuits thereof. The digital area is usually connected to the analog area via a connecting portion for preventing signals of the digital circuits from coupling to those of the analog circuits. However, when rising edges and/or falling edges of digital circuit pulses are changed sharply or electronic components of the PCB work at high frequencies, electromagnetic interference (EMI) is much greater, therefore, the EMI from the digital area can still influence the analog area via the connecting portion.

Referring to FIG. 5, a ground layer of a conventional PCB includes a digital area 10, an analog area 12, buffer areas 15, 17, and a linear connecting portion 13. The digital area 10 is mostly separated from the analog area 12 by the buffer areas 15, 17, and only connected to the analog area 12 by the connecting portion 13. A plurality of capacitors 14 are also provided in the buffer areas 15, 17, and connecting the digital area 10 and the analog area 12 to enhance the effect of preventing noise of digital signal from entering the analog area 12. Referring also to FIG. 6, a graph shows simulated amplitude response characteristics of the ground layer of FIG. 5, over a range of frequencies of a digital signal input varying from 0.0003 GHz to 6.0 GHz. It can be seen that the curve 16 remains above −40 dB over most of the range. However, according to specifications, the amplitude response of the curve 16 should be mainly below −40 dB, therefore noise of the analog area 12 is at an unacceptable level because of poor filtering effect of the connecting portion 13 and the capacitors 14.

What is desired, therefore, is a PCB having a ground layer for improving noise filtering effect thereof as well as reducing cost of the ground layer.

### SUMMARY OF THE INVENTION

In one preferred embodiment, a ground layer of a printed circuit board (PCB) includes a digital area, an analog area, and a connecting portion. The digital area is connected to the analog area via the connecting portion. The connecting portion with one end connected to the digital area, and the other end connected to the analog area follows a path resembling a labyrinth.

Other advantages and novel features will become more apparent from the following detailed description of preferred embodiments when taken in conjunction with the accompanying drawings, in which:

### BRIEF DESCRIPTION OF THE DRAWINGS

FIG. 1 is a ground layer of a PCB in accordance with a first preferred embodiment of the present invention;

FIG. 2 is a graph of amplitude response characteristics of the ground layer of FIG. 1 in use;

FIG. 3 is a ground layer of a PCB in accordance with a second preferred embodiment of the present invention;

FIG. 4 is a graph of amplitude response characteristics of the ground layer of FIG. 3 in use;

FIG. 5 is a ground layer of a conventional PCB; and

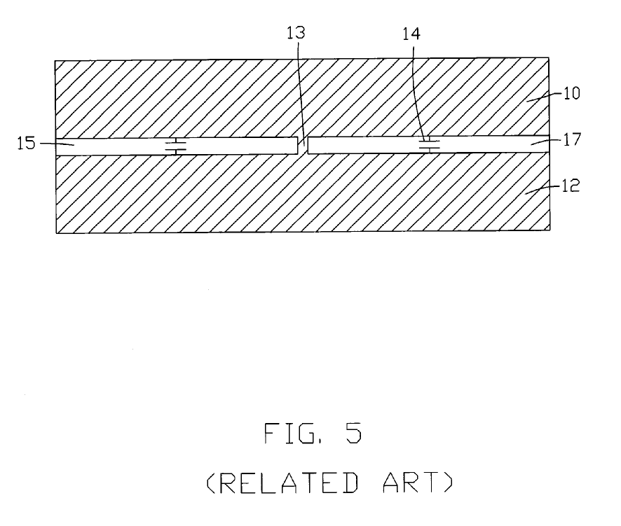

FIG. 6 is a graph of amplitude response characteristics of the ground layer of FIG. 5 in use.

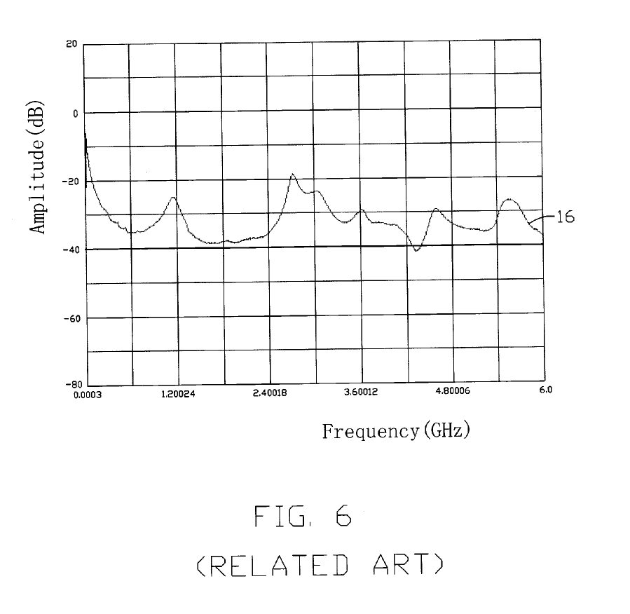

### DETAILED DESCRIPTION OF THE INVENTION

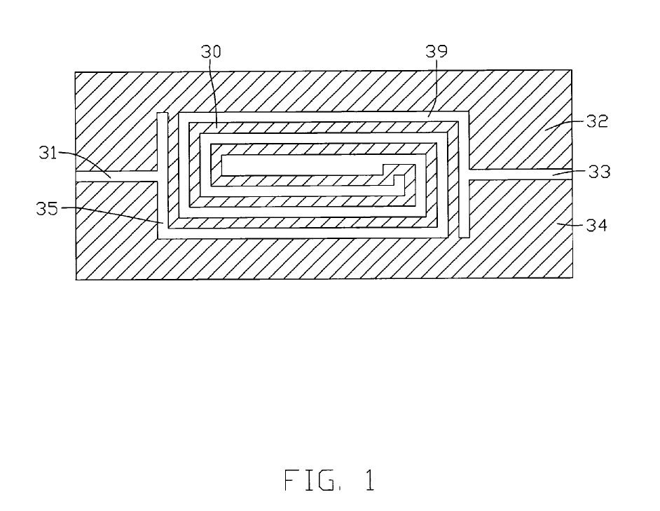

Referring to FIG. 1, a ground layer of a PCB in accordance with a first preferred embodiment of the present invention includes a digital area 32, an analog area 34, vacant areas 31, 33, 35, 39, and a connecting portion 30. The digital area 32, the analog area 34, and the connecting portion 30 are covered with copper foil. Most of the digital area 32 is separated from the analog area 34 by the vacant areas 31, 33, 35, and 39. The vacant areas 31, 33 are both straight portions with one end connecting with a part of the vacant areas 35, 39 respectively, and the other end connecting with opposite edges of the ground layer respectively. The vacant areas 35, 39 are both narrow mazelike tunnels, and generally coil shaped but with straight portions thereof superimposed into a labyrinth. Then the connecting portion 30, that is formed between the vacant areas 35, 39, follows a path resembling a labyrinth as well. The connecting portion 30 is comprised of a plurality of straight segments, and each at an angle of substantially 90 degrees with a neighboring straight segment. One end of the connecting portion 30 is connected to the digital area 32, and the other end of the connecting portion 30 is connected to the analog area 34. The two ends of the connecting portion 30 start from the digital area 32 and the analog area 34 respectively, follow anti-clockwise paths respectively, and finally meet at a center of the ground layer. The connecting portion 30 is used for filtering noise of digital signals to prevent the noise from entering the analog area 34.

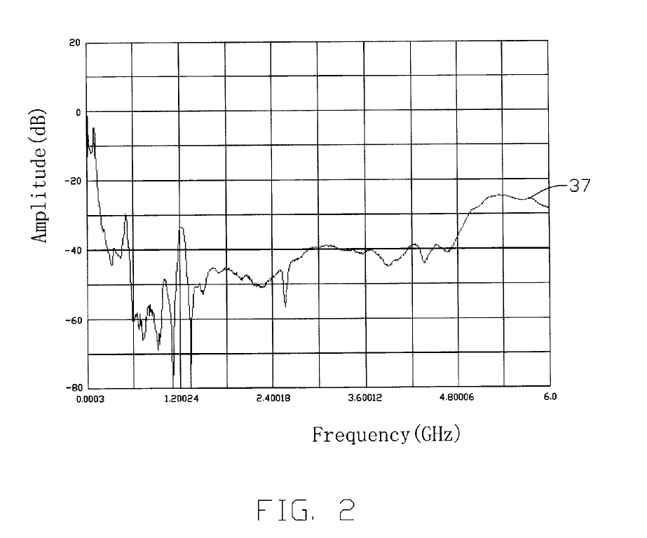

Referring also to FIG. 2, which is a graph of simulated amplitude response characteristics of the ground layer of FIG. 1. A curve 37 shows amplitude response over a range of frequencies of a digital signal input varying from 0.0003 GHz to 4.8 GHz. It can be clearly seen that the curve 37 falls below −40 dB over a broad frequency range, thus the ground layer of FIG. 1 gives superior performance in filtering noise.

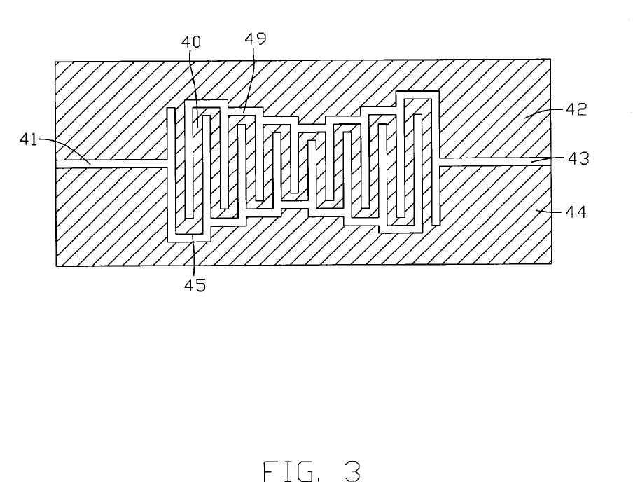

Referring to FIG. 3, a ground layer of a PCB in accordance with a second preferred embodiment of the present invention includes a digital area 42, an analog area 44, vacant areas 41, 43, 45, 49, and a connecting portion 40. The digital area 42, the analog area 44, and the connecting portion 40 are covered with copper foil. Most of the digital area 42 is separated from the analog area 44 by the vacant areas 41, 43, 45, and 49. The vacant areas 41, 43 are both straight portions with one end connecting with a part of the vacant areas 45, 49 respectively, and the other end connecting with opposite edges of the ground layer respectively. The vacant areas 45, 49 are both interleaved tunnels, and each one includes a plurality of U configurations in parallel communication with each other, and the connecting portion 40, that is formed between the vacant areas 45, 49, follows a substantially zigzag path. Heights of the U configurations gradually reduce from opposite sides of the ground layer toward a center of the ground layer, as does a height of the connecting portion 40. The connecting portion 40 is comprised of a plurality of straight segments, each at an angle of substantially 90 degrees with a neighboring straight segment. One end of the connecting portion 40 is connected to the digital area 42, and the other end of the connecting portion 40 is connected to the analog area 44. The connecting portion 40 is used for filtering noise of the digital signals to prevent the noise from entering the analog area 44.

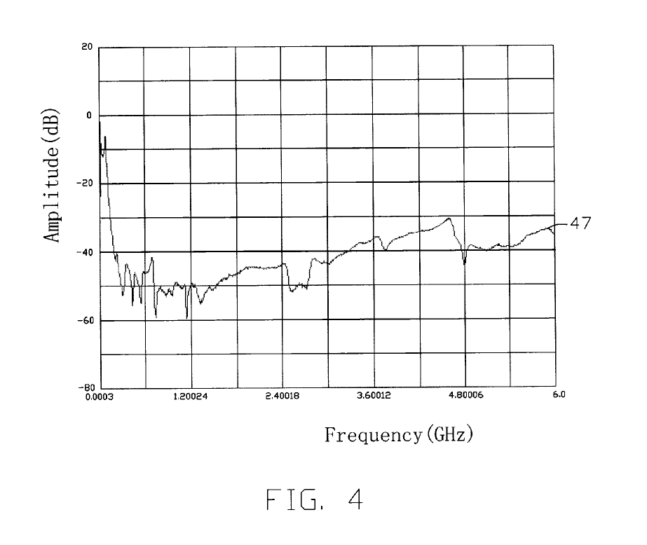

Referring also to FIG. 4, a graph of simulated amplitude response characteristics of the ground layer of FIG. 3 is shown. A curve 47 shows amplitude response over a range of frequencies of a digital signal input varying from 0.0003 GHz to 6.0 GHz. It can be clearly seen that the curve 47 falls below −40 dB over a broad frequency range, thus the ground layer of FIG. 3 gives superior performance in filtering noise.

The connecting portions 30, 40 in accordance with the preferred embodiments of the invention are made of copper foil. Further, capacitive characteristics of the connecting portions 30, 40 interleaved with the vacant areas 35, 39, 45, 49 provide noise filtering without a need for providing capacitors. Therefore, the ground layers in accordance with the preferred embodiments of the present invention give superior performance in filtering noise as well as reducing cost of the ground layers.

It is to be understood, however, that even though numerous characteristics and advantages of the preferred embodiments have been set forth in the foregoing description, together with details of the structures and functions of the embodiments, the disclosure is illustrative only, and changes may be made in detail, especially in matters of shape, size, equivalent material and arrangement of parts within the principles of the invention to the full extent indicated by the broad general meaning of the terms in which the appended claims are expressed.

What is claimed is:

1. A ground layer for a printed circuit board, comprising:
a digital area covered with copper foil;
an analog area mostly separated from the digital area, and covered with copper foil; and
a connecting portion following a path resembling a labyrinth, with one end connected to the digital area, and the other end connected to the analog area.

2. The ground layer as claimed in claim 1, wherein the connecting portion is positioned between the digital area and the analog area for filtering noise therebetween.

3. The ground layer as claimed in claim 2, wherein the ground layer further comprises a first vacant area, a second vacant area, a third vacant area, and a fourth vacant area; the first and second vacant areas are both straight portions, and with one end connecting with a part of the third and fourth vacant areas respectively, the other end connecting with opposite edges of the ground layer respectively; the connecting portion is formed between the third and fourth areas.

4. The ground layer as claimed in claim 3, wherein the third and fourth vacant areas are both narrow mazelike tunnels, and generally coil shaped but with straight portions thereof superimposed into a labyrinth.

5. The ground layer as claimed in claim 3, wherein the third and fourth vacant areas are both interleaved tunnels, and each one includes a plurality of U configurations in parallel communication with each other.

6. The ground layer as claimed in claim 5, wherein heights of the U configurations reduce from opposite sides of the ground layer toward a center of the ground layer.

7. A ground layer for a printed circuit board, comprising:
a digital ground area;
an analog ground area; and
a vacant area separating the digital ground area and the analog ground area except for a serpentine-shaped connecting portion connecting the digital ground area and the analog ground area for filtering noise of digital signals to prevent the noise from entering the analog area.

8. The ground layer as claimed in claim 7, wherein the connecting portion comprises a plurality of essentially straight segments connected to form the serpentine shape, connections between adjacent segments forming substantially right angles.

9. The ground layer as claimed in claim 8, wherein the connecting portion has two parts having ends starting from the digital ground area and the analog ground area respectively, and following clockwise paths respectively, and finally meeting at a center of the ground layer.

10. The ground layer as claimed in claim 8, wherein the connecting portion has an end starting from the digital ground area following a zigzag path, terminating at the analog ground area.

11. A ground layer for a printed circuit board, comprising:
a digital area;
an analog area; and
a vacant area substantially separating the digital ground area from the analog ground area; and
a connecting portion connecting the digital ground area and the analog ground area for filtering noise of digital signals to prevent the noise from entering the analog area, wherein the vacant area comprises two separate sections with two adjacent end portions thereof superimposed to each other and the connecting portion is formed between the two adjacent superimposed end portions.

12. The ground layer as claimed in claim 11, wherein the connecting portion comprises a plurality of continuous straight segments connected to form a serpentine shape, connections between adjacent segments forming substantially right angles.
